(19) United States
(12) Patent Application Publication
(10) Pub. No.: US 2007/0145497 A1
(43) Pub. Date: Jun. 28, 2007

(54) SEMICONDUCTOR DEVICE

(76) Inventor: Young Suk Ko, Incheon (KR)

Correspondence Address: SHERR & NOURSE, PLLC, 620 HERNDON PARKWAY, SUITE 200, HERNDON, VA, 20170, US

(21) Appl. No.: 11/616,271

(22) Filed: Dec. 26, 2006

(30) Foreign Application Priority Data
Dec. 27, 2005 (KR) 10-2005-130860

(51) Int. Cl. H01L 29/76

(52) U.S. Cl. 257/409

(57) ABSTRACT

Embodiments relate to a semiconductor device including an impurity region formed in the semiconductor device; an insulating layer formed on the impurity region; and a contact formed to have a certain step difference in the impurity region through the insulating layer.

The present application claims priority under 35 U.S.C. 119 and 35 U.S.C. 365 to Korean Patent Application No. 10-2005-130860 (filed on Dec. 27, 2005), which is hereby incorporated by reference in its entirety.

### BACKGROUND

In a semiconductor substrate, an active area may be connected to an external terminal through a contact. Accordingly, the contact may function as a signal transfer path between a device and the external terminal. In such a process, a contact resistance of the contact may have impact performance criteria of the device, such as a signal transfer speed. Accordingly, it may be important to minimize the contact resistance.

FIG. 1 is an example sectional diagram of a related art semiconductor device.

Referring to FIG. 1, impurity region 110 may be formed in a prescribed upper portion of semiconductor substrate 100. For a typical Metal Oxide Silicon Field Effect Transistor (MOSFET), impurity region 110 may become a source region or a drain region. Impurity region 110 may also become a contact region within a well region.

Pre Metal Dielectric (PMD) insulating layer 120 may be formed on semiconductor substrate 100 having impurity region 110. A contact hole may be formed through a certain region of PMD insulating layer 120, and impurity region 110 may be exposed to the contact hole. Contact flag 130 may contact impurity region 110 through the contact hole. Contact layer 140 may be formed on the upper surface of contact flag 130.

In the contact of a related art semiconductor device as described above, a contact area that may influence a contact resistance of the contact may be limited to an area in which the upper surface of impurity region 110 is in contact with the lower surface of contact flag 130.

However, as semiconductor devices become more highly integrated, a size of a contact hole for contact flag 130 may become gradually smaller. As a result, an area in which the upper surface of impurity region 110 is in contact with the lower surface of contact flag 130 may be gradually reduced. Contact resistance may increase as the contact area decreases.

In a related art semiconductor device having the contact as described above, the contact resistance may increase with the high integration of a device. Hence, operational characteristics of a device may deteriorate.

### SUMMARY

Embodiments relate to a semiconductor device and a method for manufacturing the same.

Embodiments relate to a semiconductor device that may be capable of improving the property of a device by reducing contact resistance, and a method for manufacturing the same.

According to embodiments, a semiconductor device may include an impurity region formed in the semiconductor device, an insulating layer formed on the impurity region, and a contact formed to have a certain step difference in the impurity region through the insulating layer.

According to embodiments, a method for manufacturing a semiconductor device may include forming an impurity region in the semiconductor device, forming an insulating layer on an upper portion of the impurity region, and forming a contact to have a certain step difference in the impurity region through the insulating layer.

### BRIEF DESCRIPTION OF THE DRAWINGS

FIG. 1 is an example sectional diagram of a related art semiconductor device;

FIG. 2 is an example sectional diagram of a semiconductor device according to embodiments; and

FIGS. 3 to 8 are example sectional diagrams illustrating a method for manufacturing a semiconductor device according to embodiments.

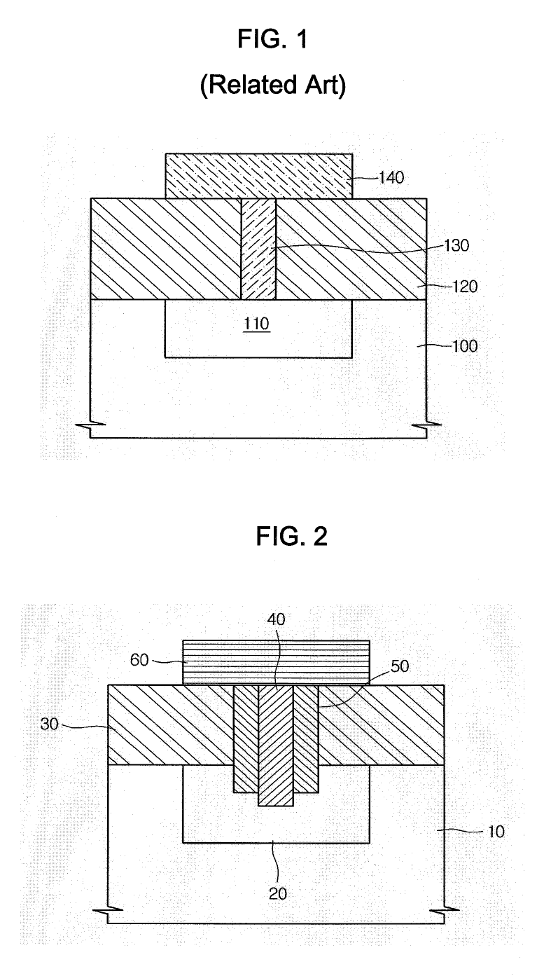

### DETAILED DESCRIPTION OF EMBODIMENTS

Referring to FIG. 2, impurity region 20 may be formed in a prescribed upper portion of semiconductor substrate 10. Impurity region 20 may become a source region, or may also become a drain region. Impurity region 20 may also become a contact region within a well region, if necessary. Insulating layer 30 may be formed on semiconductor substrate 10 having impurity region 20. Insulating layer 30 may be PMD insulating layer 30.

Portions of PMD insulating layer 30 may be etched to be exposed to impurity region 20. Etched impurity region 20 may have a prescribed step difference.

In embodiments, a step difference may be formed, for example in impurity region 20. This may result in a contact area of first contact 40, second contact 50, and impurity region 20 being increasingly widened. As the contact area is widened, contact resistance may be increasingly reduced. Accordingly, operational characteristics of the device may be improved.

First contact 40 and second contact 50 may make contact with impurity region 20 through the etched portion.

FIG. 2 shows one pair of step differences in impurity region 20. However, additional step differences may also be formed in order to increase the contact area. The bottom surfaces of first contact 40 and second contact 50 being in contact with impurity region 20 may be cornered or rounded.

First contact 40 and second contact 50 may be made from a metal, for example with high conductivity. In embodiments, first contact 40 and second contact 50 may be made from tungsten W.

First contact 40 may make contact with impurity region 20 more deeply as compared to second contact 50. Therefore, a portion of impurity region 20 that may be in contact with first contact 40 may be more deeply etched than a portion being in contact with second contact 50.

Third contact 60 may be formed on first contact 40 and second contact 50.

In embodiments, the number of electrodes being in contact with impurity region 20 may be limited to two, i.e. first contact 40 and second contact 50. In embodiments, many more contacts may make contact with impurity region 20 by many more step differences.

In embodiments as described above, a contact area between the impurity region and the contacts may be increased and/or widened by additional step differences, and contact resistance may be reduced.

As first contact 40 and second contact 50 make contact with impurity region 20 by the contact in a wider area, contact resistance may be reduced and thus operational characteristics of the device may be improved.

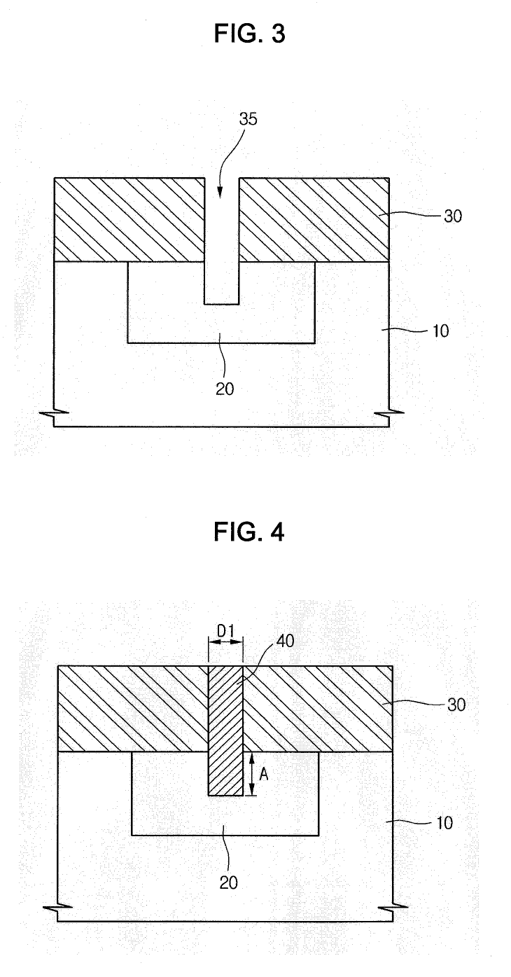

FIGS. 3 to 8 illustrate a method for manufacturing a semiconductor device according to embodiments.

Referring to FIG. 3, insulating layer 30 may be formed on semiconductor substrate 10 having impurity region 20 formed in a prescribed upper portion thereof. In embodiments, impurity region 20 may become a source region, or may also become a drain region.

Impurity region 20 may be made from a first conductor, i.e. an n-type conductor, or a second conductor, i.e. a p-type conductor. In embodiments, insulating layer 30 may be a PMD insulating layer, which may be formed through a Plasma Enhanced Chemical Vapor Deposition (PECVD) method, but is not limited only to this method.

Referring to FIG. 4, a photo resist pattern (not shown) may be formed on insulating layer 30 through a photolithography process. Insulating layer 30 may be etched up to first depth A in impurity region 20 by using the photo resist pattern as a mask. In this way, first contact hole 35 may be formed through insulating layer 30, and may have a first diameter D1. If first contact hole 35 is formed, the photo resist pattern may be removed.

A first metal material may be deposited on semiconductor substrate 10 through a CVD method, and may be polished through a Chemical Mechanical Polishing (CMP) process until insulating layer 30 is exposed.

According to embodiments, in first contact hole 35, first contact 40 with first diameter D1 and first depth A may make contact with impurity region 20.

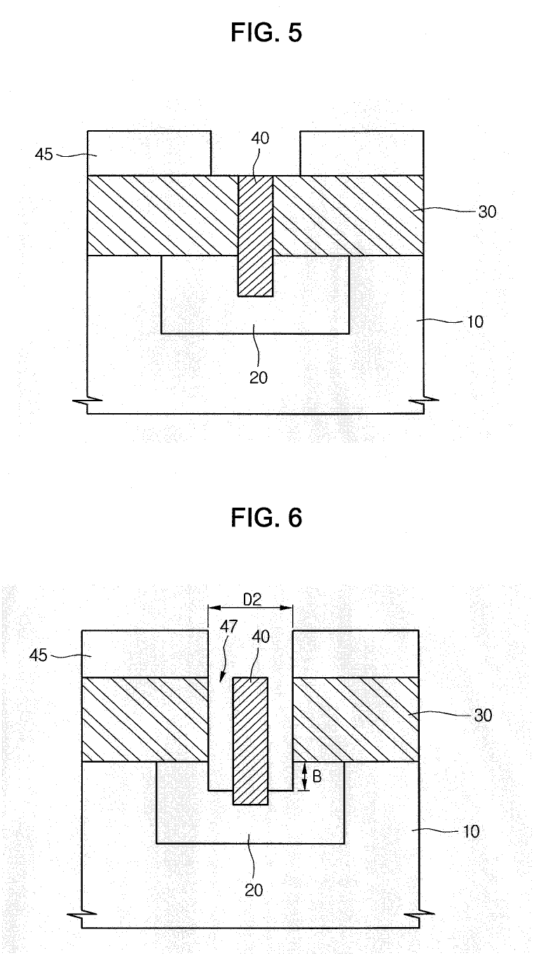

Referring to FIG. 5, photo resist pattern 45 may be formed on semiconductor substrate 10, for example through a photolithography process. According to embodiments, the exposure width of photo resist pattern 45 may be formed to be greater than first diameter D1.

Referring to FIG. 6, insulating layer 30 may be etched up to second depth B in impurity region 20 by using photo resist pattern 45 and first contact 40 as a mask.

In this way, second contact hole 47 may be formed through insulating layer 30, and may have second diameter D2. Second contact hole 47 may be formed to be adjacent to first contact 40.

Second contact hole 47 may be formed to be adjacent to both sides of first contact 40. Second contact hole 47 may also be formed to be adjacent to one side of first contact 40, if necessary. Second diameter D2 may have the same size as the exposure width of photo resist pattern 45.

Second diameter D2 of second contact hole 47 may be at least greater than first diameter D1 of first contact hole 35, and second depth B may be smaller than first depth A. In embodiments, second depth B may also be formed to be greater than first depth A.

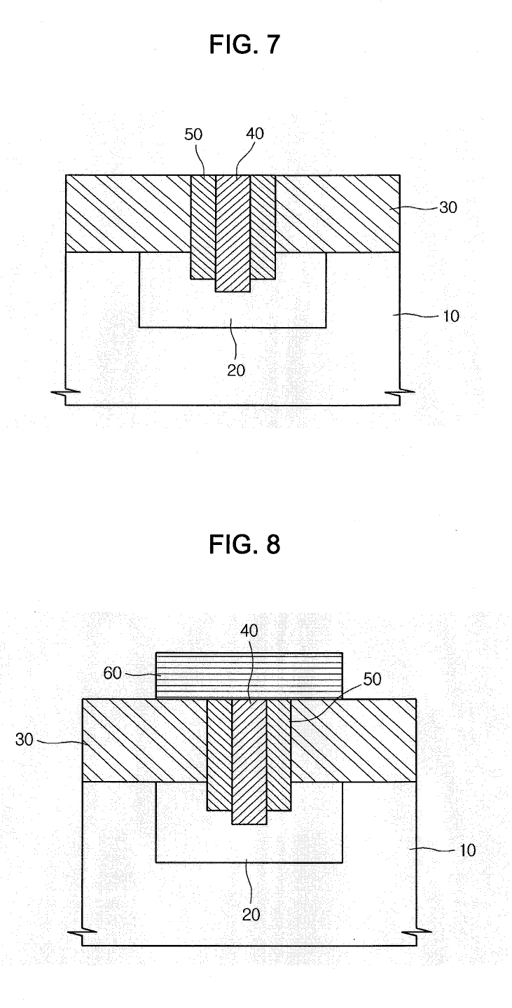

Referring to FIG. 7, a second metal material may be deposited on semiconductor substrate 10 through a CVD method, and may be polished through a CMP process until insulating layer 30 is exposed. Accordingly, in second contact hole 47, second contact 50 with second diameter D2 and second depth B may make contact with impurity region 20.

Second contact 50 and first contact 40 may also be made from the same metal material, or different metal materials. In embodiments, first contact 40 and second contact 50 may be made from tungsten W. Further, first contact 40 may be made from tungsten W, and second contact 50 may be made from aluminum Al.

According to embodiments, the impurity region may be etched so that contacts 40 and 50 have at least one step difference, contacts may be formed in each step difference, and each of the contacts may make contact with the impurity region in a wider region, so that contact resistance may be reduced and thus the property of the device may be improved.

Referring to FIG. 8, a third metal material may be deposited on semiconductor substrate 10 through a CVD method, and may be patterned and annealed. Third contact 60, which may be in contact with first contact 40 and second contact 50, may thus be formed. It is preferred that third contact 60 may be formed to cover the upper surfaces of first contact 40 and second contact 50. Third contact 60 may be made from metal materials different from those of first contact 40 and second contact 50. According to embodiments, third contact 60 may be made from aluminum Al.

According to embodiments as described above, an impurity region may be etched so that a certain step difference may be formed therein, contacts may be formed in each step difference, and a contact area between the contact and the impurity region is maximized. In this way, contact resistance may be minimized and thus operational characteristics of a device may be improved.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. A device comprising:
an impurity region formed in a semiconductor device;
an insulating layer formed over the impurity region; and
a contact configured formed through the insulating layer and in the impurity region and configured to have a prescribed step difference within the impurity region.

2. The device of claim 1, wherein the contact comprises at least two contacts formed to have different depths within the impurity region.

3. The device of claim 1, wherein the contact comprises a first contact and a second contact, and a step difference is formed in the impurity region by the first contact and the second contact.

4. The device of claim 2, wherein the first contact is formed in to have a greater depth in the impurity region by the step difference than the second contact.

5. The device of claim 1, wherein a bottom surface of the contact is substantially flat, and a junction between the bottom surface and side surfaces of the contact substantially comprises a right angle.

6. The device of claim 6, wherein a bottom surface of the contact is substantially rounded.

7. A method comprising:
forming an impurity region in a semiconductor device; and
forming a contact within the insulating layer to have a least one step difference in the impurity region, such that a first portion of the contact has a depth different than a second portion of the contact.

8. The method of claim 7, further comprising forming an insulating layer on an upper portion of the impurity region, where in the contact is formed through the insulating layer.

9. The method of claim 7, wherein forming the contact comprises:
forming the first portion by etching the insulating layer up to a first depth A in the impurity region; and
forming the second portion by etching the insulating layer adjacent to the first contact up to a second depth B in the impurity region.

10. The method of claim 9, wherein the first depth is greater than the second depth.

11. The method of claim 9, wherein the second depth is greater than the first depth.

12. The method of claim 9, wherein a diameter of the second depth is greater than a diameter of the first depth.

13. The method of claim 9, wherein the first contact is used as a mask to form the second contact.

14. A device comprising:
an impurity region formed in a semiconductor device; and
a contact formed within the impurity region having a first portion with a first width and at a first depth below a surface of the impurity region, and a second portion having a second width and at a second depth below the surface, wherein the second width is greater than the first width, and wherein the first depth is not equal to the second depth.

15. The device of claim 14, further comprising an insulating layer formed over the impurity region and the substrate, wherein the contact extends through the insulating layer.

16. The device of claim 14, wherein the first depth is greater than the second depth.

17. The device of claim 14, wherein the first portion of the contact is formed of a first conductive material and the second portion of the contact is formed of a second conductive material.

18. The device of claim 17, wherein the first portion of the contact comprises tungsten, and the second portion of the contact comprises aluminum.

19. The device of claim 18, wherein the first and second portions of the contact comprise tungsten.

20. The device of claim 14, wherein the impurity region comprises at least one of a source and a drain.
